(19) United States
(12) Patent Application Publication
(10) Pub. No.: US 2020/0185597 A1
(43) Pub. Date: Jun. 11, 2020

(54) MEMORY DEVICE AND MANUFACTURING METHOD THEREOF

(71) Applicant: UNITED MICROELECTRONICS CORP., Hsin-chu City (TW)

(72) Inventors: Kun-Ju Li, Tainan City (TW); Hsin-Jung Liu, Pingtung County (TW); I-Ming Tseng, Kaohsiung City (TW); Chau-Chung Hou, Tainan City (TW); Yu-Lung Shih, Tainan City (TW); Fu-Chun Hsiao, Changhua County (TW); Hui-Lin Wang, Taipei City (TW); Tzu-Hsiang Hung, Kaohsiung City (TW); Chih-Yueh Li, Taipei City (TW); Ang Chan, Taipei City (TW); Jing-Yin Jhang, Tainan City (TW)

(21) Appl. No.: 16/216,969

(22) Filed: Dec. 11, 2018

(51) Int. Cl. H01L 43/02; H01L 27/22; H01L 43/10; H01L 43/12

(52) U.S. Cl. CPC H01L 43/02; H01L 43/12; H01L 43/10; H01L 27/222

(57) ABSTRACT

A memory device includes an insulation layer, a memory cell region and an alignment mark region are defined on the insulation layer, an interconnection structure disposed in the insulation layer, a dielectric layer disposed on the insulation layer and the interconnection structure, the dielectric layer is disposed within the memory cell region and the alignment mark region, a conductive via plug disposed on the interconnection structure within the memory cell region, the conductive via plug has a concave top surface, an alignment mark trench penetrating the dielectric layer within the alignment mark region, a bottom electrode disposed on the conductive via plug within the memory cell region and disposed in the alignment mark trench within the alignment mark region, and a magnetic tunnel junction (MTJ) structure disposed on the bottom electrode within the memory cell region and disposed in the alignment mark trench within the alignment mark region.

### BACKGROUND OF THE INVENTION

### 1. Field of the Invention

The present invention relates to a memory device, and more particularly, to a memory device including an alignment mark trench.

### 2. Description of the Prior Art

The manufacture of integrated circuits keeps improving as the related technologies progress. Many kinds of electric circuits may be integrated and formed on a single chip. The semiconductor processes for forming integrated circuits including semiconductor devices and/or memory devices may include many steps, such as a deposition process for forming a thin film, a photoresist coating process, an exposure process, and a develop process for forming a patterned photoresist, and an etching process for patterning the thin film. In the exposure process, a photomask having a pattern to be formed has to be aligned with a base layer pattern on a substrate for transferring the pattern to a specific location on the substrate. The alignment marks may be used to assist the alignment in the exposure process and to monitor overlay results for reducing the influence of process variations on the production yield. However, as the semiconductor process becomes more complicated, problems about manufacturing and measurements of alignment marks are generated accordingly and have to be solved.

### SUMMARY OF THE INVENTION

The present invention provides a memory device, the memory device includes an insulation layer, wherein a memory cell region and an alignment mark region are defined on the insulation layer, an interconnection structure disposed in the insulation layer, a dielectric layer disposed on the insulation layer and the interconnection structure, wherein the dielectric layer is disposed within the memory cell region and the alignment mark region, a conductive via plug disposed on the interconnection structure and penetrating the dielectric layer within the memory cell region, wherein the conductive via plug has a concave top surface, an alignment mark trench penetrating the dielectric layer within the alignment mark region, a bottom electrode disposed on the conductive via plug within the memory cell region and disposed in the alignment mark trench within the alignment mark region, and a magnetic tunnel junction (MTJ) structure disposed on the bottom electrode within the memory cell region and disposed in the alignment mark trench within the alignment mark region.

The present invention provides a method for forming a memory device, first, an insulation layer is provided, a memory cell region and an alignment mark region are defined on the insulation layer, an interconnection structure is then formed in the insulation layer, a dielectric layer is formed on the insulation layer and the interconnection structure, the dielectric layer is disposed within the memory cell region and the alignment mark region, next, a conductive via plug is formed on the interconnection structure and penetrating the dielectric layer within the memory cell region, wherein the conductive via plug has a concave top surface, at least two alignment mark trenches are formed penetrating the dielectric layer within the alignment mark region, afterwards, a bottom electrode is formed on the conductive via plug within the memory cell region and disposed in the alignment mark trenches within the alignment mark region, and a magnetic tunnel junction (MTJ) structure is formed on the bottom electrode within the memory cell region and in the alignment mark trenches within the alignment mark region.

In the memory device and the manufacturing method thereof according to the present invention, apart of the MTJ film stack layer is disposed on the conductive via plug within the memory cell region, and another part of the MTJ film stack layer is disposed in the alignment mark trenches within the alignment mark region. The connection hole and the alignment mark trench may be formed by the same process for improving the alignment condition between the connection structure and other structures subsequently formed on the connection structure. Additionally, in the present invention, the alignment mark trenches TR is formed after the planarization process for forming the conductive via plug 40, and the bottom electrode 60 is then formed on the concave top surface of the conductive via plug 40. Besides, an out gassing process is performed after the conductive via plug 40 is formed. In this way, if a heating step is performed in the manufacturing process, the air gap between the conductive via plug and the bottom electrode is not easy to expand, avoiding the bottom electrode to bulge, thereby improving the yield of the semiconductor element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are schematic drawings illustrating a manufacturing method of a memory device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8.

FIG. 10 shows the schematic drawing illustrating a memory device according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

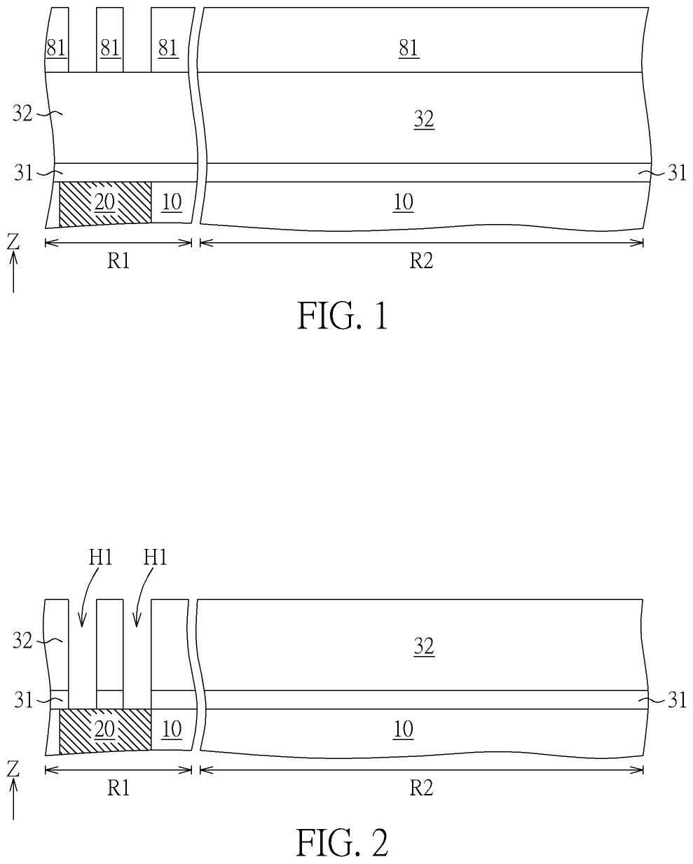

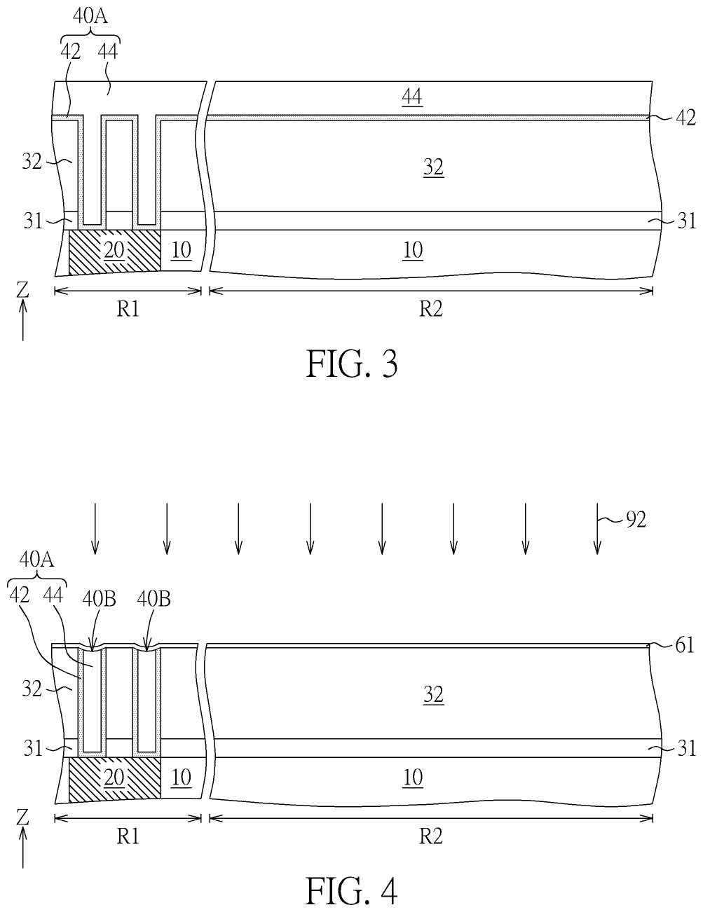

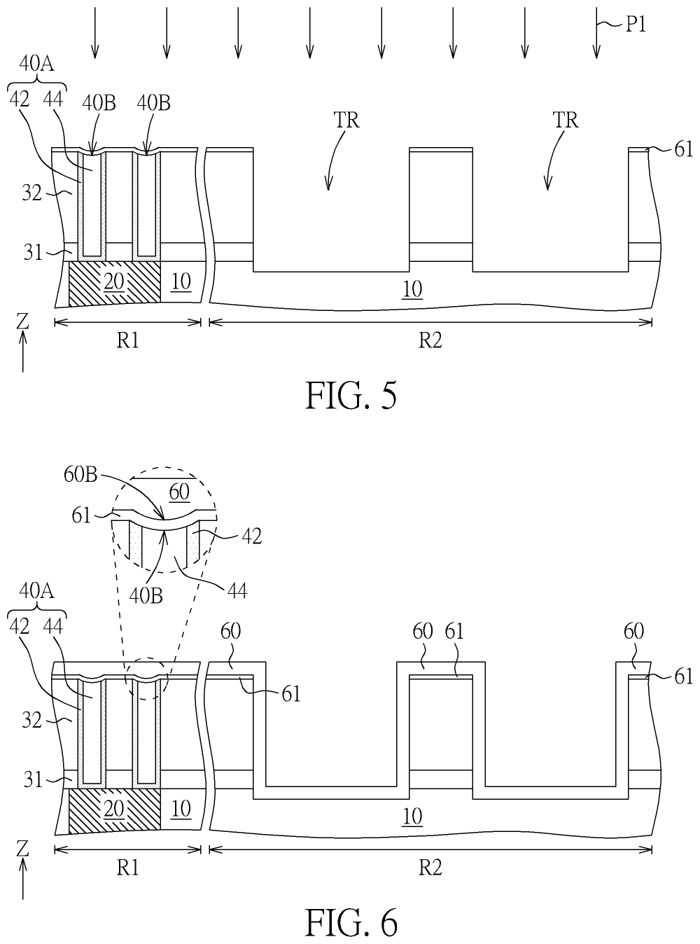

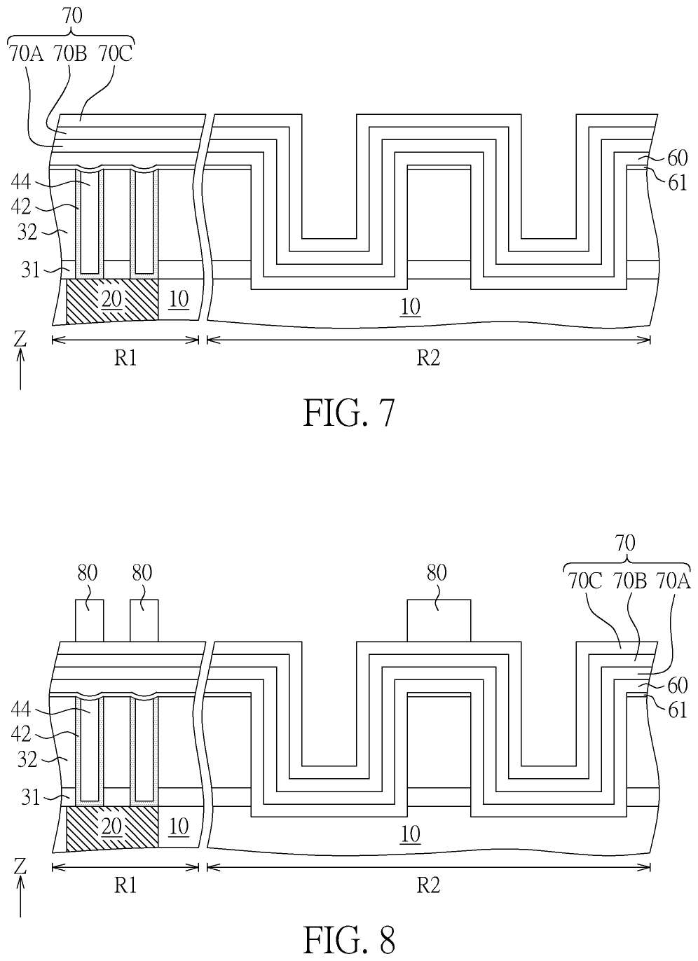

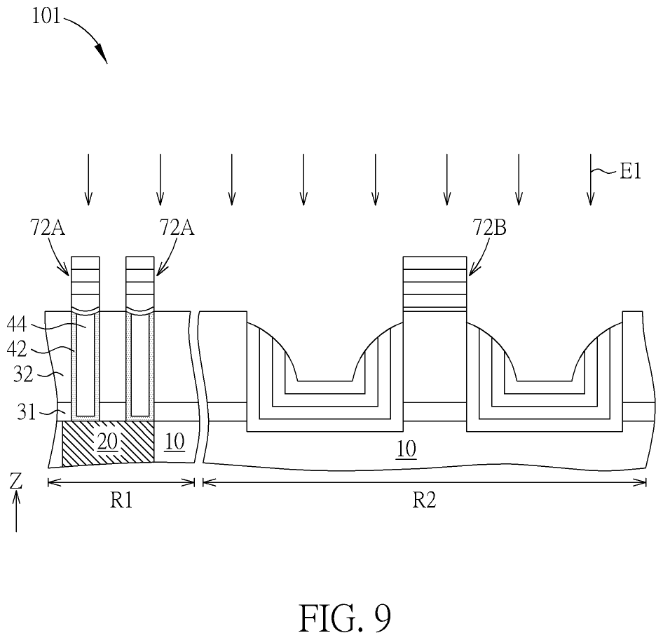

Please refer to FIGS. 1-9. FIGS. 1-9 are schematic drawings illustrating a manufacturing method of a memory device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8. The manufacturing method of a memory device in this embodiment may include the following steps. As shown in FIG. 1, an insulation layer 10 is provided, and an interconnection structure 20 is formed in the insulation layer 10. In some embodiments, a memory cell region R1 and an alignment mark region R2 may be defined on the insulation layer 10. The interconnection structure 20 may be disposed in the memory cell region R1, and the alignment mark region R2 may include an alignment mark region, but not limited thereto. In some embodiments, the insulation layer 10 may be disposed on a substrate (not shown), but not limited thereto. The substrate mentioned above may include a semiconductor substrate or a non-semiconductor substrate. The semiconductor substrate may include a silicon substrate, a silicon germanium substrate, or a silicon-on-insulator (SOI) substrate, and the non-semiconductor substrate may include a glass substrate, a plastic substrate, or a ceramic substrate, but not limited thereto. In addition, other devices, such as transistors, may be formed on the substrate before the steps of forming the insulation layer 10 and the interconnection structure 20 according to some considerations, and a memory structure subsequently formed on the interconnection structure 20 may be electrically connected to other devices via the interconnection structure 20 and/or other connection structures, but not limited thereto.

As shown in FIG. 1, one or more dielectric layers may be formed covering the insulation layer 10 and the interconnection structure 20. For example, a first dielectric layer 31 and a second dielectric layer 32 may be sequentially formed covering the insulation layer 10 and the interconnection structure 20 in a thickness direction Z of the insulation layer 10, but not limited thereto. In some embodiments, the insulation layer 10, the first dielectric layer 31, and the second dielectric layer 32 may respectively include dielectric materials such as silicon oxide, silicon nitride, silicon oxynitride, tetraethoxysilane (TEOS), nitrogen doped carbide (NDC), or other suitable dielectric materials, and the material composition of the first dielectric layer 31 may be different from the material composition of the second dielectric layer 32 for etching selectivity concerns in the subsequent processes, but not limited thereto. The interconnection structure 20 may include a conductive material and/or a barrier material. The barrier material mentioned above may include titanium (Ti), titanium nitride (TiN), tantalum (Ta), tantalum nitride (TaN), tungsten silicide (WSi), tungsten nitride (WN), or other suitable barrier materials. The conductive material mentioned above may include aluminum (Al) , tungsten (W) , copper (Cu) , titanium aluminide (TiAl), or other suitable low resistivity materials.

As shown in FIG. 1 and FIG. 2, at least one connection hole H1 may be formed penetrating the first dielectric layer 31 and the second dielectric layer 32 on the interconnection structure 20 for exposing a part of the interconnection structure 20. The connection hole H1 may be formed through a photolithography process, for example, a first patterned photoresist layer 81 may be formed on the second dielectric layer 32, and an etching process using the first patterned photoresist layer 81 as a mask may be performed to form the connection hole H1 within the memory cell region R1.

As shown in FIGS. 3-5, a conductive via plug 40 is then formed on the insulation layer 10. The conductive via plug 40 is formed in the connection hole H1. Specifically, the method of forming the conductive via plug 40 may include but is not limited to the following steps. As shown in FIG. 3, a first conductive layer 40A may be formed after the step of forming the connection hole H1. The first conductive layer 40A may be formed on the insulation layer 10, the first dielectric layer 31, the second dielectric layer 32, and the interconnection structure 20. In some embodiment, the connection hole H1 may be fully filled with the first conductive layer 40A. The first conductive layer 40A may be a single layer structure or a multiple layer structure including a barrier material 42 and a low resistivity material 44 disposed above the barrier material 42. The barrier material 42 mentioned above may include titanium, titanium nitride, tantalum, tantalum nitride, tungsten silicide, tungsten nitride, or other suitable barrier materials. The low resistivity material mentioned above may include aluminum, tungsten, copper, titanium aluminide, or other suitable low resistivity materials. As shown in FIG. 4, a removing process 92 may be performed to remove the first conductive layer 40A outside the connection hole H1 for forming the conductive via plug 40. The removing process 92 may include a chemical mechanical polishing (CMP) process or other suitable removing approaches. It is worth noting that during the CMP process, the speed of removing the first conductive layer 40A is faster due to the matching of the polishing slurry, so that the top surface of the conductive via plug 40 is easily over-polished, and a concave top surface 40B is then formed on the top of the conductive via plug 40.

As shown in FIG. 5, after the conductive via plugs 40 are formed within the memory cell region R1, a plurality of alignment mark trenches TR are then formed within the alignment mark region R2. In some embodiments, the alignment mark trench TR and the connection hole H1 (shown in FIG. 3) may be formed by the same process, and the width of the alignment mark trench TR may be larger than the width and/or the diameter of the connection hole H1. In some embodiments, a bottom surface of the alignment mark trench TR (such as the bottommost surface of the alignment mark trench TR) may be lower than a bottom surface of the connection hole H1 (such as the bottommost surface of the connection hole H1) and a top surface of the interconnection structure 20 in the thickness direction Z of the insulation layer 10, but the present invention is not limited thereto. Therefore, in some embodiments, the alignment mark trench TR may be partly disposed in the insulation layer 10, but not limited thereto. Besides, since the alignment mark trenches TR are formed after the conductive via plug 40 is formed, so the barrier material 42 and a low resistivity material 44 of the conductive via plug 40 do not disposed in each alignment mark trench TR.

In some embodiment of the present invention, as shown in FIGS. 4-5, before the bottom electrode 60 and the alignment mark trenches TR are formed, further comprising forming a buffer layer 61 on the second dielectric layer 32 and on the conductive via plugs 40. The buffer layer 61 is made of the same material as the material of the following formed bottom electrode 60 (such as titanium nitride), and the thickness of the buffer layer 61 is less than 5 nm. Forming a buffer layer 61 can help the subsequent bottom electrode 60 to better attach to the conductive via plug 40. Furthermore, since the buffer layer 61 is formed before the alignment mark trenches TR are formed, so the buffer layer 61 is not located in each alignment mark trench TR.

In addition, after the conductive via plugs 40 are formed, as shown in FIG. 5, an out gassing process P1 may be additionally performed. In the present invention, the out gassing process P1 may be performed before or after the alignment mark trenches TR are formed. The out gassing process includes heating the wafer to a temperature at or more than 500K in a vacuum environment for more than 60 seconds. The purpose of performing the out gassing process is to eliminate excess impurities or air in the conductive via plug, or to remove the residue on the wafer surface. In the subsequent steps, a bottom electrode will be formed on the conductive via plug. Since the conductive via plug has a concave top surface, therefore there may be an air gap between the bottom electrode and the top surface of the conductive via plug. If a heating step is performed in a subsequent step, the air gap may expand, causing the bottom electrode to bulge, thereby affecting the yield of the semiconductor element.

As shown in FIGS. 6-9, a bottom electrode 60 is formed on the conductive via plugs 40 and in each alignment mark trench TR. Since each conductive via plug 40 has a concave top surface, and the bottom electrode conformally covers on the concave top surface, so the bottom electrode 60 that disposed on the conductive via plugs 40 has a convex bottom surface 60B that corresponding to the concave top surface of the conductive via plugs 40. In some embodiments, the bottom electrode may include metallic materials, such as titanium, titanium nitride, tantalum, tantalum nitride, platinum (Pt), ruthenium (Ru), a stack layer of the above-mentioned materials, an alloy of the above-mentioned materials, or other suitable conductive materials.

Next, as shown in FIG. 7, a magnetic tunnel junction (MTJ) film stack layer 70 is formed on the bottom electrode 60. More precisely, the MTJ film stack layer 70 is disposed on the conductive via plug 40 within the memory cell region R1, and disposed in each alignment mark trench TR within the alignment mark region R2. Therefore, the MTJ film stack layer 70 has a flat cross sectional profile within the memory cell region R1, and has an U-shaped cross sectional profile in the alignment mark trenches TR within the alignment mark region R2. In some embodiments, the MTJ film stack layer 70 includes suitable memory element materials, such as a resistive memory element material, a phase change memory element material, or a ferroelectric memory element material. The MTJ film stack layer 70 mentioned above at least include a pinned layer 70A, an insulating layer 70B and a free layer 70C sequentially stacked with one another in the thickness direction Z of the insulation layer 10, but not limited thereto. The components of the MTJ film stack 70 may be modified and/or include other material layers according to other design considerations. The pinned layer 70A in the MTJ film stack layer 70 may include a synthetic antiferromagnetic layer and a reference layer. The synthetic antiferromagnetic layer may include antiferromagnetic materials such as iron manganese (FeMn) or cobalt/platinum (Co/Pt) multilayer for a perpendicularly magnetized MTJ, but not limited thereto. The free layer 70C in the MTJ film stack layer 70 and the reference layer in the pinned layer 70A may include ferromagnetic materials such as cobalt, iron (Fe), cobalt-iron (CoFe), cobalt-iron-boron (CoFeB), or other suitable ferromagnetic materials. The insulating layer 70B in the MTJ film stack layer 70 may include insulation materials such as magnesium oxide (MgO) , aluminum oxide, or other suitable insulation materials. In some embodiments, the bottom electrode 60 and the MTJ film stack layer 70 may be formed by deposition processes, such as a physical vapor deposition (PVD) process and/or a chemical vapor deposition (CVD) process, but not limited thereto.

Finally, as shown in FIGS. 8-9, in some embodiments, a patterned photoresist layer 80 may be formed on the MTJ film stack layer 70 within the memory cell region R1. In some embodiment the patterned photoresist layer 80 also disposed on parts of the MTJ film stack layer 70 within alignment mark region R2, and an etching process E1 using the patterned photoresist layer 80 as a mask may be performed to etch the MTJ film stack layer 70 and the bottom electrode 60. After the etching process El is performed, at least one MTJ structure 72A is formed, disposed on and electrically connected to the conductive via plugs 40. Besides, in some embodiment, a dummy MTJ structure 72B is formed within the alignment mark region R2, the dummy MTJ structure 72B and the bottom electrode 60 are disposed on the second dielectric layer 32, and disposed between two adjacent alignment mark trenches TR. In addition, parts of the bottom electrode 60 and the MTJ film stack layer 70 still remained in each adjacent alignment mark trench TR.

As shown in FIG. 9, a memory device 101 may be formed by the manufacturing method described above. The memory device 101 in this embodiment may include the insulation layer 10, the interconnection structure 20, the first dielectric layer 31, the second dielectric layer 32, the connection hole H1, the alignment mark trench TR, the conductive via plugs 40, the bottom electrode 60, and the MTJ structure 72A (in some embodiment, further comprising the dummy MTJ structure 72B) . The memory cell region R1 and the alignment mark region R2 are defined on the insulation layer 10. The interconnection structure 20 is disposed in the insulation layer 10. The first dielectric layer 31 and the second dielectric layer 32 are disposed on the insulation layer 10 and the interconnection structure 20. The first dielectric layer 31 and the second dielectric layer 32 are disposed within the memory cell region R1 and the alignment mark region R2. The connection hole H1 is disposed on the interconnection structure 20 and penetrates the first dielectric layer 31 and the second dielectric layer 32 within the memory cell region R1. The alignment mark trenches TR penetrates the first dielectric layer 31 and the second dielectric layer 32 within the alignment mark region R2. The conductive via plugs 40 is disposed on the insulation layer 10. The conductive via plugs 40 includes a barrier layer 42 and a conductive layer 44 disposed in the connection hole H1. The conductive via plug 40 has a concave top surface 40B. The bottom electrode 60 disposed on the conductive via plug 40 within the memory cell region R1 and disposed in the alignment mark trenches TR within the alignment mark region R2. The magnetic tunnel junction (MTJ) structure 72A disposed on the bottom electrode 60 within the memory cell region R1, and parts of the MTJ film stack layer 70 is disposed in the alignment mark trenches R2 within the alignment mark region R2.

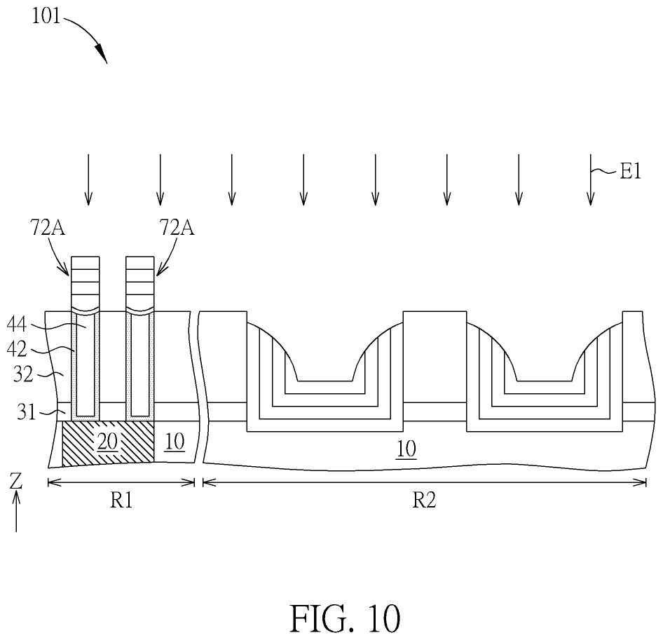

In other embodiment of the present invention, please refer to FIG. 10, which shows the schematic drawing illustrating a memory device according to another embodiment of the present invention. As shown FIG. 10, compared with FIGS. 8-9, in this embodiment, the method for forming the patterned photoresist layer 80 maybe omitted, therefore after the etching process E1 is performed, the dummy MTJ structure 72B (shown in FIG. 9) will not be formed. Besides, the buffer layer 61 disposed between the two alignment mark trenches TR may also be removed during the etching process E1. Except for the features mentioned above, the other components, material properties, and manufacturing method of this embodiment are similar to the first preferred embodiment detailed above and will not be redundantly described.

To summarize the above descriptions, in the memory device and the manufacturing method thereof according to the present invention, a part of the MTJ film stack layer 70 is disposed on the conductive via plug 40 within the memory cell region R1, and another part of the MTJ film stack layer 70 is disposed in the alignment mark trenches TR within the alignment mark region R2. The connection hole and the alignment mark trench may be formed by the same process for improving the alignment condition between the connection structure and other structures subsequently formed on the connection structure. Additionally, in the present invention, the alignment mark trenches TR is formed after the planarization process which is performed for forming the conductive via plug 40, and the bottom electrode 60 is then formed on the concave top surface of the conductive via plug 40. Besides, an out gassing process is performed after the conductive via plug 40 is formed. In this way, if a heating step is performed in the manufacturing process, the air gap between the conductive via plug and the bottom electrode is not easy to expand, avoiding the bottom electrode to bulge, thereby improving the yield of the semiconductor element.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device, comprising:
an insulation layer, wherein a memory cell region and an alignment mark region are defined on the insulation layer;
an interconnection structure disposed in the insulation layer;
a dielectric layer disposed on the insulation layer and the interconnection structure, wherein the dielectric layer is disposed within the memory cell region and the alignment mark region;
a conductive via plug disposed on the interconnection structure and penetrating the dielectric layer within the memory cell region, wherein the conductive via plug has a concave top surface;
an alignment mark trench penetrating the dielectric layer within the alignment mark region;
a bottom electrode disposed on the conductive via plug within the memory cell region and disposed in the alignment mark trench within the alignment mark region; and
a magnetic tunnel junction (MTJ) structure disposed on the bottom electrode within the memory cell region and disposed in the alignment mark trench within the alignment mark region.

2. The memory device of claim 1, wherein the alignment mark trench is partly disposed in the insulation layer, and the bottom surface of the alignment mark trench is lower than the top surface of the interconnection structure in a thickness direction of the insulation layer.

3. The memory device of claim 1, wherein the conductive via plug comprises a barrier layer and a conductive layer disposed in a connection hole, wherein the conductive layer is disposed on the barrier layer.

4. The memory device of claim 3, wherein the barrier layer is not disposed in the alignment mark trench.

5. The memory device of claim 1, wherein the bottom electrode on the conductive via plug has a convex bottom surface.

6. The memory device of claim 1, wherein the MTJ structure comprises a pinned layer, an insulating layer and a free layer sequentially stacked from bottom to top.

7. The memory device of claim 1, wherein the MTJ structure disposed in the alignment mark trench has an U-shaped cross sectional profile.

8. The memory device of claim 1, further comprising a second alignment mark trench disposed beside the alignment mark trench.

9. The memory device of claim 8, further comprising a dummy MTJ structure disposed on the dielectric layer within the alignment mark region, and wherein the dummy MTJ structure is disposed between the alignment mark trench and the second alignment mark trench.

10. A method for forming a memory device, comprising:
providing an insulation layer, wherein a memory cell region and an alignment mark region are defined on the insulation layer;
forming an interconnection structure in the insulation layer;
forming a dielectric layer on the insulation layer and the interconnection structure, wherein the dielectric layer is disposed within the memory cell region and the alignment mark region;
forming a conductive via plug on the interconnection structure and penetrating the dielectric layer within the memory cell region, wherein the conductive via plug has a concave top surface;
forming at least two alignment mark trenches penetrating the dielectric layer within the alignment mark region;
forming a bottom electrode on the conductive via plug within the memory cell region and disposed in the alignment mark trenches within the alignment mark region; and
forming a magnetic tunnel junction (MTJ) structure on the bottom electrode within the memory cell region and in the alignment mark trenches within the alignment mark region.

11. The method of claim 10, wherein the step for forming the bottom electrode further comprising:
forming a buffer layer on the dielectric layer before the alignment mark trench is formed, wherein parts of the buffer layer that is disposed on the conductive via plug has a concave cross sectional profile; and
forming the bottom electrode after the alignment mark trench is formed, wherein the buffer layer and the bottom electrode comprise a same material.

12. The method of claim 10, further comprising performing an out-gassing process after the conductive via plug is formed.

13. The method of claim 12, wherein the out-gassing process comprising:
heating in a vacuum state for more than 60 seconds at a temperature greater than 500K.

14. The method of claim 10, further comprising forming a barrier layer in a connection hole before the conductive via plug is formed.

15. The method of claim 14, wherein the barrier layer is not disposed in the alignment mark trench.

16. The method of claim 10, after the conductive via plug is formed, further comprising performing a planarization process to the conductive via plug, and to make the conductive via plug has the concave top surface.

17. The method of claim 10, wherein the bottom electrode on the conductive via plug has a convex bottom surface.

18. The method of claim 10, wherein the MTJ structure comprises a pinned layer, an insulating layer and a free layer sequentially stacked from bottom to top.

19. The method of claim 10, wherein the MTJ structure disposed in the alignment mark trench has an U-shaped cross sectional profile.
